(19) United States
(12) Patent Application Publication
(10) Pub. No.: US 2015/0118463 A1
(43) Pub. Date: Apr. 30, 2015

(54) WIRING BOARD

(71) Applicant: KYOCERA Circuit Solutions, Inc., Yasu-shi (JP)

(72) Inventor: Satoshi NAKAMURA, Omihachiman-shi (JP)

(73) Assignee: KYOCERA Circuit Solutions, Inc., Yasu-shi (JP)

(21) Appl. No.: 14/519,303

(22) Filed: Oct. 21, 2014

(30) Foreign Application Priority Data
Oct. 31, 2013 (JP) 2013-226098

(51) Int. Cl. H05K 1/03

(52) U.S. Cl. CPC H05K 1/038; H05K 1/0306
USPC 428/212

(57) ABSTRACT

Provided is a wiring board including an insulating board, and a wiring conductor formed on upper and lower surfaces of the insulating board, the wiring conductor including a differential line having two parallel strip-shaped conductors on the insulating board, the insulating board having a glass cloth and an insulating resin portion, in which the glass cloth is a bundle of glass fibers woven in a matrix, contains gaps, and has uneven surfaces, the insulating resin portion has flat surfaces and is formed on upper and lower surfaces of the glass cloth so as to fill the gaps and reduce the unevenness, and a difference in the dielectric constant between the glass cloth and the insulating resin portion is not larger than 0.5.

### BACKGROUND OF THE INVENTION

1. Field of the Invention

The present invention relates to a wiring board for mounting thereon a semiconductor element.

2. Description of Related Art

In recent years, with high-speed operations of electronic devices represented by portable game machines and communication devices, high-speed transmission of signals has been demanded for wiring boards used in the electronic devices. Methods for achieving such high-speed transmission include a signal transmission system called differential transmission (see Japanese Unexamined Patent Publication No. 2009-259879, for example).

The “differential transmission” is a signal transmission system that uses a differential line having two parallel strip-shaped conductors. One of the strip-shaped conductors receives a differential signal with a positive voltage and the other receives a differential signal with a negative voltage, and the difference between the differential signals is obtained at a reception unit to read a signal. Therefore, reading a signal is easy if signals to be sent to the strip-shaped conductors have only small amplitudes. This leads to reduction in the time required for forming the amplitudes of differential signals, and high-speed signal transmission is thus achieved.

FIG. 2 is a schematic cross-sectional view of a conventional wiring board B using a differential transmission system. The wiring board B includes an insulating board 11, a wiring conductor 12, and a solder resist layer 13.

The insulating board 11 includes a glass cloth 14, an insulating resin portion 15, and a plurality of through-holes 11b penetrating the insulating board 11 in a vertical direction. The insulating board 11 has a mounting portion 11a for mounting a semiconductor element S thereon at the center of the upper surface of the insulating board 11.

The wiring conductor 12 is made of copper plating or copper foil, for example, and is formed on the upper and lower surfaces of the insulating board 11 and on the inner surface of the through-holes 11b. The wiring conductor 12 on the upper surface of the insulating board 11 includes a differential line 16 having two parallel stripe-shaped conductors. A portion of the wiring conductor 12 on the upper surface of the insulating board 11 serves as a semiconductor element connection pad 17 which is connected to the semiconductor element S. A portion of the wiring conductor 12 on the lower surface of the insulating board 11 serves as an external connection pad 18 which is connected to an external circuit board.

The solder resist layer 13 is made of thermosetting resin such as polyimide resin and formed on the upper and lower surfaces of the insulating board 11. The solder resist layer 13 on the upper surface of the insulating board 11 has an opening 13a for allowing the semiconductor element connection pad 17 to be exposed to the outside, and the solder resist layer 13 on the lower surface of the insulating board 11 has an opening 13b for allowing the external connection pad 18 to be exposed to the outside.

The semiconductor element connection pad 17 is connected to an electrode T of the semiconductor element S and the external connection pad 18 is connected to a wiring conductor of the external electric circuit board, so that the semiconductor element S is electrically connected to an external electric circuit board. Further, the semiconductor element S starts operating when a signal is transmitted between the semiconductor element S and the external electric circuit board via the wiring conductor 12 and the differential line 16.

In the conventional wiring board B, the insulating board 11 includes the glass cloth 14 and the insulating resin portion 15 as described above.

The glass cloth 14 is a bundle of glass fibers woven in a matrix. The glass cloth 14 contains gaps and has uneven surfaces. The insulating resin portion 15 has flat surfaces and is formed on the upper and lower surfaces of the glass cloth 14 so as to fill the gaps and reduce the unevenness. The glass cloth 14 and the insulating resin portion 15 have dielectric constants of approximately 6 and 3, respectively, which means that the difference in the dielectric constant between the glass cloth 14 and the insulating resin portion 15 is approximately 3.

When the insulating board 11 described above is provided with the differential line 16 on the surface thereof, the unevenness on the surfaces of the glass cloth 14 sometimes makes a distance T1 smaller than a distance T2 as shown in FIG. 3, for example, the distance T1 being a distance between a strip-shaped conductor 16a of the differential line 16 and the glass cloth 14 immediately below the conductor 16a and the distance T2 being a distance between a strip-shaped conductor 16b and the glass cloth 14 immediately below the conductor 16b. In that case, the strip-shaped conductor 16a receives more influence of the dielectric constant from the glass cloth 14 immediately below the conductor 16a than the strip-shaped conductor 16b receives from the glass cloth 14 immediately below the strip-shaped conductor 16b. Hence, the strip-shaped conductor 16a transmits a signal at a lower rate than the strip-shaped conductor 16b since the conductor 16a is strongly affected by the dielectric constant of the glass cloth 14, which is larger than that of the insulating resin portion 15. In other words, a difference is caused in the signal transmission rate between the strip-shaped conductors 16a and 16b. This makes it more difficult to transmit an excellent signal from an external electric circuit board to the semiconductor element S, which may result in unstable operations of the semiconductor element S.

### SUMMARY OF THE INVENTION

A main object of the present invention is to provide a wiring board that allows a semiconductor element to carry out stable operations by transmitting an excellent signal.

The present invention provides a wiring board including an insulating board, and a wiring conductor formed on upper and lower surfaces of the insulating board, the insulating board having a glass cloth and an insulating resin portion, in which the glass cloth is a bundle of glass fibers woven in a matrix, contains gaps, and has uneven surfaces, the insulating resin portion has flat surfaces and is formed on upper and lower surfaces of the glass cloth so as to fill the gaps and reduce the unevenness, and a difference in a dielectric constant between the glass cloth and the insulating resin portion is not larger than 0.5.

In the wiring board according to the present invention, the difference in the dielectric constant between the glass cloth and the insulating resin portion of the insulating board is set to be not larger than 0.5. Hence, even when the unevenness on the surfaces of the glass cloth causes a difference between a first distance and a second distance, the first distance being a distance between a first one of the strip-shaped conductors of the differential line and the glass cloth immediately below the first conductor and the second distance being a distance between a second one of the strip-shaped conductors and the glass cloth immediately below the second conductor, the difference in the influence of the dielectric constant that the first and second strip-shaped conductors receive from the glass cloth can be reduced. Hence, it becomes possible to reduce the difference in the rates at which a signal transmits through the first and second strip-shaped conductors. In this way, there is achieved a wiring board that is capable of transmitting an excellent signal at a high rate from an external electric circuit board to a semiconductor element, thereby obtaining stable operations of the semiconductor element.

### BRIEF DESCRIPTION OF THE DRAWINGS

FIG. 1 is a schematic cross-sectional view of a wiring board according to an embodiment of the present invention;

FIG. 2 is a schematic cross-sectional view of a conventional wiring board; and

FIG. 3 is an enlarged view of the main part of the conventional wiring board.

### DESCRIPTION OF THE PREFERRED EMBODIMENTS

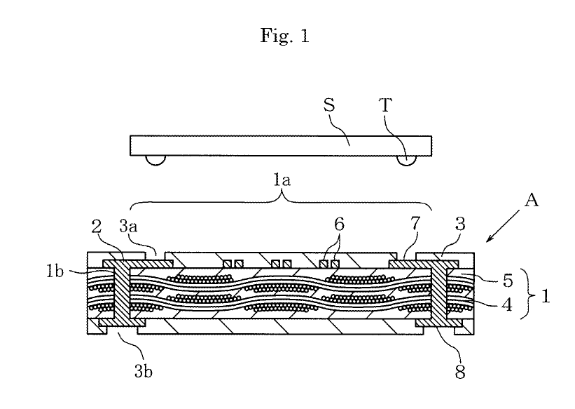

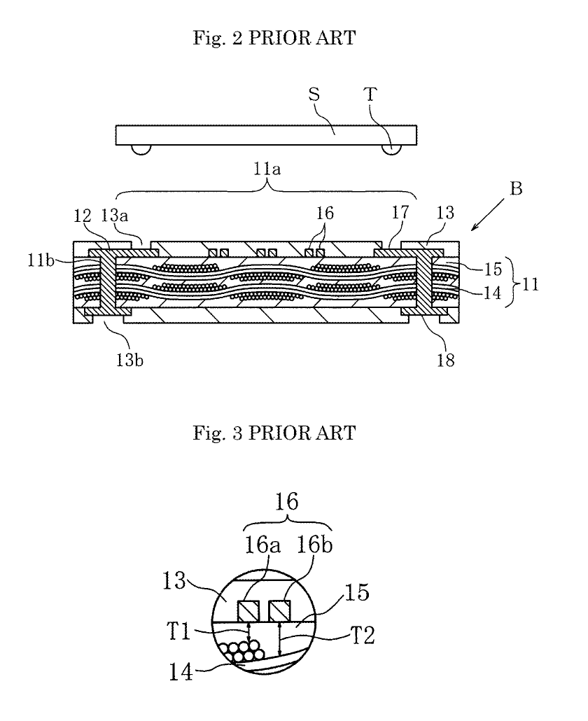

A wiring board A according to an embodiment of the present invention will be described with reference to FIG. 1.

The wiring board A includes an insulating board 1, a wiring conductor 2, and a solder resist layer 3.

The insulating board 1 includes a glass cloth 4 and an insulating resin portion 5. The glass cloth 4 is made by weaving a bundle of glass fibers such as glass yarn in a matrix. Examples of weaving methods include plain weaving, diagonal weaving, and sateen weaving. The glass cloth 4 contains gaps and has uneven surfaces. The insulating resin portion 5 has flat surfaces and is formed on the upper and lower surfaces of the glass cloth 4 so as to fill the gaps and reduce the unevenness. Examples of the glass fibers forming the glass cloth 4 include NE glass and S glass. The glass cloth 4 has a dielectric constant in the range of approximately 4.6 to 5.2. In order to make the dielectric constant of the glass cloth 4 fall within the above range, the type and weaving density, for example, of the glass fibers need to be adjusted. Examples of the glass cloth 4 with a dielectric constant in the above range include “NE-Glass” manufactured by Nitto Boseki Co., Ltd.

The insulating resin portion 5 is made of epoxy resin or polyimide resin, for example, and has a dielectric constant in the range of approximately 4.1 to 5.7. In order to make the dielectric constant of the insulating resin portion 5 fall within the above range, a suitable material needs to be selected from epoxy resin or polyimide resin. Between the strip-shaped conductors of the differential line 6 and the surface of the glass cloth 4 immediately below the conductors, a resin layer exists preferably having a thickness of approximately 5 μm to 10 μm. Examples of the insulating resin portion 5 with a dielectric constant in the above range include “MCL-I-671” manufactured by Hitachi Chemical Co., Ltd. The materials of the glass cloth 4 and the insulating resin portion 5 are appropriately selected so that the difference in the dielectric constant therebetween is not larger than 0.5, and the insulating board 1 is formed by combining the glass cloth 4 and the insulating resin portion 5.

The insulating board 1 has a mounting portion 1a for mounting a semiconductor element S thereon at the center of the upper surface of the insulating board 1. Further, the insulating board 1 has a plurality of through-holes 1b penetrating the insulating board 1 in a vertical direction. Furthermore, the wiring conductor 2 is formed on the upper and lower surfaces of the insulating board 1 and on the inner surface of the through-holes 1b.

It is to be note that although the insulating board 1 has a single-layered structure in the embodiment, it may have a multi-layered structure having a lamination of insulating layers made of one or at least two different electrical insulating materials. For example, an alternating arrangement of the glass cloth 4 and the insulating resin layer may form the insulating board 1.

The wiring conductor 2 is formed of metal excellent in conductivity such as copper plating or copper foil by a well known semi-additive process or subtractive process. The wiring conductor 2 is formed on the upper and lower surfaces of the insulating board 1 and on the inner surface of the through-holes 1b. The wiring conductor 2 on the upper surface of the insulating board 1 includes a plurality of differential lines 6 each including two parallel strip-shaped conductors. The distance between strip-shaped conductors in a pair is preferably in the range of 7.5 μm to 60 μm. The differential lines 6 each has a width of approximately 5 μm to 25 μm.

A portion of the wiring conductor 2 on the upper surface of the insulating board 1 serves as a semiconductor element connection pad 7 which is connected to the semiconductor element S. A portion of the wiring conductor 2 on the lower surface of the insulating board 1 serves as an external connection pad 8 which is connected to an external circuit board.

The solder resist layer 3 is made of thermosetting resin such as polyimide resin and formed on the upper and lower surfaces of the insulating board 1. The solder resist layer 3 on the upper surface of the insulating board 1 has an opening 3a for allowing the semiconductor element connection pad 7 to be exposed to the outside, and the solder resist layer 3 on the lower surface of the insulating board 1 has an opening 3b for allowing the external connection pad 8 to be exposed to the outside.

The semiconductor element connection pad 7 is connected to the electrode T of the semiconductor element S and the external connection pad 8 is connected to the wiring conductor of the external electric circuit board so that the semiconductor element S is electrically connected to an external electric circuit board. Further, the semiconductor element S starts operating when a signal is transmitted between the semiconductor element S and the external electric circuit board via the wiring conductor 2 and the differential lines 6.

In the wiring board A, the difference in the dielectric constant between the glass cloth 4 and the insulating resin portion 5 of the insulating board 1 is set to be not larger than 0.5. Hence, even when the unevenness on the surfaces of the glass cloth 4 causes a difference between a first distance and a second distance, the first distance being a distance between a first one of the strip-shaped conductors of the differential line 6 and the surface of the glass cloth 4 immediately below the first conductor and the second distance being a distance between a second one of the strip-shaped conductors of the differential line 6 and the surface of the glass cloth 4 immediately below the second conductor, the difference in the influence of the dielectric constant that the first and second strip-shaped conductors receive from the glass cloth 4 can be reduced. Hence, it becomes possible to reduce the difference in the rates at which a differential signal transmits through the first and second strip-shaped conductors. In this way, there is achieved the wiring board A that is capable of transmitting an excellent signal at a high rate from an external electric circuit board to the semiconductor element S, thereby obtaining stable operations of the semiconductor element S.

As is obvious from the above descriptions, the glass cloth 4 and the insulating resin portion 5 may have the same dielectric constant.

Examples of the possible combinations of the glass cloth and the insulating resin portion of which difference in the dielectric constant is set to be not larger than 0.5 include a glass cloth contained “NE-Glass” (dielectric constant: 4.6) and an insulating resin portion contained “MCL-I-671” (dielectric constant: 4.2 to 4.4). In that combination, the difference in the dielectric constant is 0.2 to 0.4.

The wiring board A is manufactured by penetrating the through-holes 1b through the insulating board 1 contained the glass cloth 4 and the insulating resin portion 5, subsequently, forming the wiring conductor 2 made of copper plating on the inner surface of the through-holes 1b and on the both main surfaces of the insulating board 1, and then forming the solder resist layer 3 thereon.

While preferred embodiments of the invention have been described, it is to be understood that changes and variations may be made without departing from the spirit or scope of the following claims. For example, although the insulating resin portion 5 in the embodiment does not include an inorganic filler, the insulating resin portion may include an inorganic filler dispersed therein. Examples of the inorganic filler include silica, titanium oxide, and alumina. In a case where the insulating resin portion includes an inorganic filler, it is important that the difference in the dielectric constant between the insulating resin portion and the glass cloth is set to be not larger than 0.5.

What is claimed is:

1. A wiring board comprising:
an insulating board; and
a wiring conductor formed on upper and lower surfaces of the insulating board, the insulating board having a glass cloth and an insulating resin portion,
wherein the glass cloth is a bundle of glass fibers woven in a matrix, contains gaps, and has uneven surfaces,
the insulating resin portion has flat surfaces and is formed on upper and lower surfaces of the glass cloth so as to fill the gaps and reduce the unevenness, and
a difference in a dielectric constant between the glass cloth and the insulating resin portion is not larger than 0.5.

2. The wiring board according to claim 1, wherein the wiring conductor includes a differential line having two parallel strip-shaped conductors on the insulating board.

3. The wiring board according to claim 1, wherein the glass cloth has a dielectric constant in a range of 4.6 to 5.2.

4. The wiring board according to claim 1, wherein the insulating resin portion has a dielectric constant in a range of 4.1 to 5.7.

5. The wiring board according to claim 1, wherein the insulating resin portion includes an inorganic filler.
